(19) United States
(12) Patent Application Publication
(10) Pub. No.: US 2026/0076150 A1
(43) Pub. Date: Mar. 12, 2026

(54) LASER PROCESSING DEVICE AND LASER PROCESSING METHOD

(71) Applicant: IBIDEN CO., LTD., Ogaki, Gifu (JP)

(72) Inventors: Kohei SUZUKI, Ogaki (JP); Takumi INAGAKI, Ogaki (JP); Osamu INAGAWA, Ogaki (JP)

(73) Assignee: IBIDEN CO., LTD., Ogaki, Gifu (JP)

(21) Appl. No.: 19/255,046

(22) Filed: Jun. 30, 2025

(30) Foreign Application Priority Data
Jul. 1, 2024 (JP) 2024-106269

(51) Int. Cl. H01L 21/66; B23K 26/03; B23K 26/04; B23K 26/06; B23K 26/402; B23K 103/00; H01L 21/48; H01L 21/67; H01L 23/498

(52) U.S. Cl. CPC H10P 74/238; B23K 26/032; B23K 26/04; B23K 26/0626; B23K 26/0648; B23K 26/402; H10P 72/0436; H10P 72/0604; H10W 70/05; H10W 70/685; B23K 2103/42

(57) ABSTRACT

A laser processing device for forming an opening in an insulating layer of a wiring substrate includes a light source that emits a laser beam, an objective lens that focuses the laser beam onto a surface of a wiring substrate, a control device including circuitry that controls an irradiation condition of the laser beam, and a sensor that outputs to the control device a sensor output based on plasma light emitted from the wiring substrate due to irradiation of the laser beam. The circuitry of the control device recognizes a change in an irradiation site of the laser beam based on the sensor output, reduces processing capability of the laser beam and continues the irradiation upon.

### CROSS-REFERENCE TO RELATED APPLICATIONS

The present application is based upon and claims the benefit of priority to Japanese Patent Application No. 2024-106269, filed Jul. 1, 2024, the entire contents of which are incorporated herein by reference.

### BACKGROUND OF THE INVENTION

### FIELD OF THE INVENTION

The present invention relates to a laser processing device and a laser processing method.

### Description of Background Art

Japanese Patent Application Laid-Open Publication No. 2013-43198 describes a drilling method and a laser processing device for forming a laser-processed hole. The entire contents of this publication are incorporated herein by reference.

### SUMMARY OF THE INVENTION

According to one aspect of the present invention, a laser processing device for forming an opening in an insulating layer of a wiring substrate includes a light source that emits a laser beam, an objective lens that focuses the laser beam onto a surface of a wiring substrate, a control device including circuitry that controls an irradiation condition of the laser beam, and a sensor that outputs to the control device a sensor output based on plasma light emitted from the wiring substrate due to irradiation of the laser beam. The circuitry of the control device recognizes a change in an irradiation site of the laser beam based on the sensor output, reduces processing capability of the laser beam and continues the irradiation upon.

According to another aspect of the present invention, a laser processing method for a wiring substrate includes irradiating an insulating layer of a wiring substrate with a laser beam such that an opening is formed in the insulating layer and exposes a portion of a conductor layer covered by the insulating layer, and causing a sensor to output a sensor output based on plasma light emitted from the wiring substrate irradiated with the laser beam. The irradiating includes recognizing a change in an irradiation site of the laser beam based on the sensor output, and reducing processing capability of the laser beam based on the sensor output while continuing irradiation of the laser beam.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic diagram illustrating an example of an overall structure of a laser processing device according to an embodiment of the present invention;

FIG. 2 is a cross-sectional view illustrating an example of a wiring substrate processed using a laser processing device and method according to embodiments of the present invention;

FIG. 3 is a cross-sectional view illustrating an example of a processing state by a laser processing device and method according to embodiments of the present invention;

FIG. 4A is a cross-sectional view illustrating an example of a progress state of processing by a laser processing device and method according to embodiments of the present invention;

FIG. 4B is a cross-sectional view illustrating an example of a progress state of processing by a laser processing device and method according to embodiments of the present invention;

FIG. 5 illustrates an example of frequency characteristics of filters in a laser processing device according to an embodiment of the present invention;

FIG. 6A shows an example of measurement results of sensor outputs of a laser processing device according to an embodiment of the present invention;

FIG. 6B shows an example of measurement results of sensor outputs of a laser processing device according to an embodiment of the present invention;

FIG. 6C shows an example of measurement results of sensor outputs of a laser processing device according to an embodiment of the present invention;

FIG. 6D shows an example of measurement results of sensor outputs of a laser processing device according to an embodiment of the present invention;

FIG. 7A is an observation image of an opening formed at the time when the measurement results of FIG. 6A were obtained;

FIG. 7B is an observation image of an opening formed at the time when the measurement results of FIG. 6B were obtained;

FIG. 7C is an observation image of an opening formed at the time when the measurement results of FIG. 6C were obtained; and

FIG. 7D is an observation image of an opening formed at the time when the measurement results of FIG. 6D were obtained.

### DETAILED DESCRIPTION OF THE EMBODIMENTS

Embodiments will now be described with reference to the accompanying drawings, wherein like reference numerals designate corresponding or identical elements throughout the various drawings.

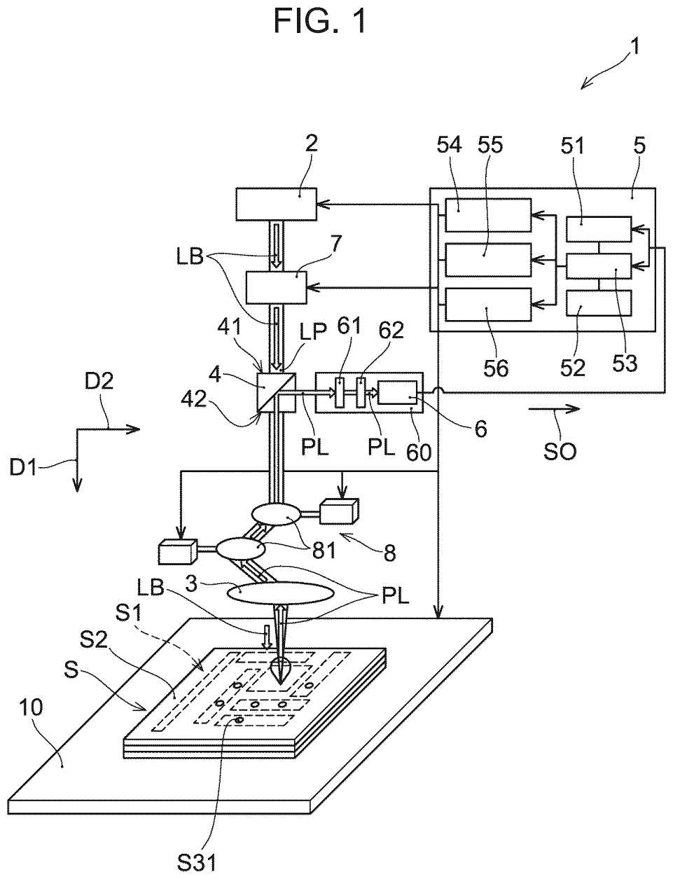

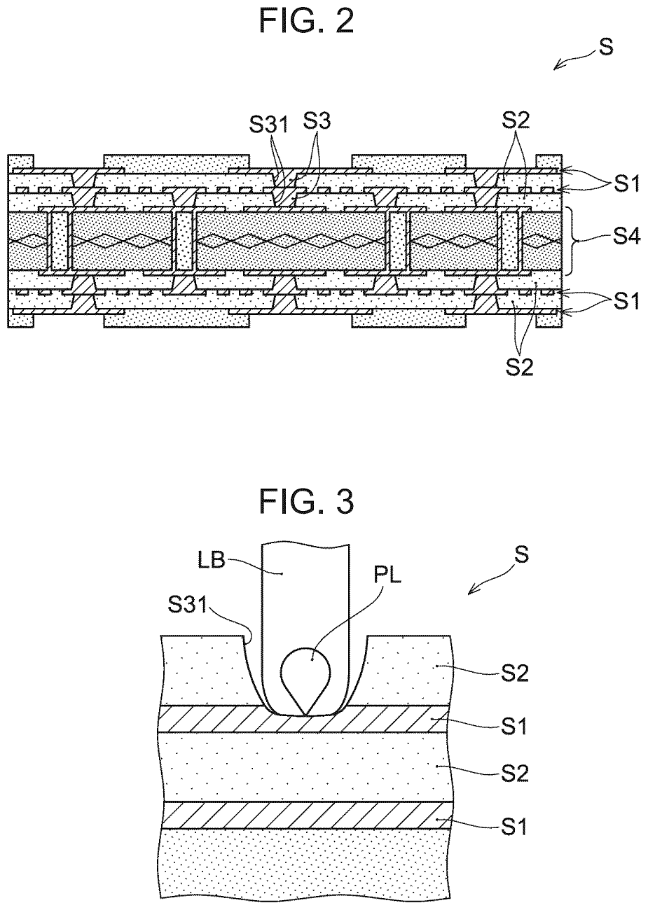

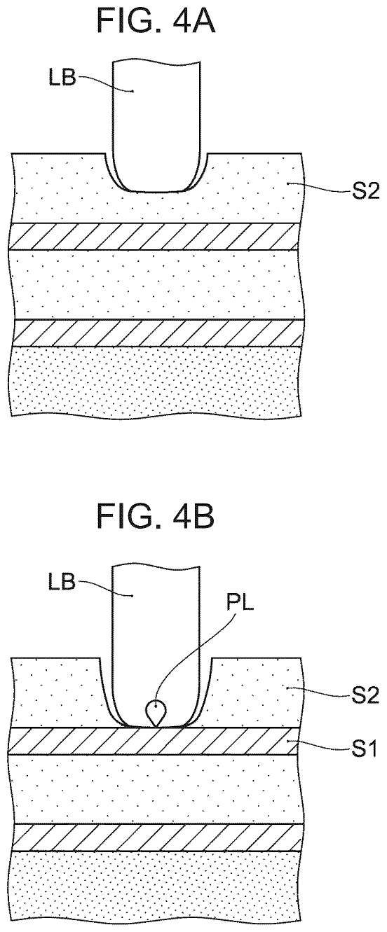

FIG. 1 schematically illustrates an overall structure of a laser processing device 1, which is an example of the laser processing device according to the embodiment. FIG. 2 illustrates a cross-sectional view of a wiring substrate (S), which is an example of a processing target according to the laser processing device and laser processing method of the embodiment. Further, FIG. 3 illustrates an example of a processing state at an irradiation spot of a laser beam according to the laser processing device and laser processing method of the embodiment. The laser processing device 1 in FIG. 1 is merely one example of the laser processing device of the embodiment. The laser processing device of the embodiment may include any additional structural elements and/or functional blocks in addition to those included in the laser processing device 1 in FIG. 1, and may omit some of the structural elements included in the laser processing device 1. Further, a wiring substrate processed by the laser processing device and laser processing method of the embodiment may have any structure different from the structure of the wiring substrate (S) illustrated in FIG. 2. The laser processing device and laser processing method of the embodiment can be applied to a wiring substrate having any structure that includes at least one conductor layer and one insulating layer covering the conductor layer.

### Structure of Laser Processing Device

As illustrated in FIG. 1, the laser processing device 1 includes a light source 2 that emits a laser beam (LB), an objective lens 3 that focuses the laser beam (LB), a control device 5 that controls irradiation conditions of the laser beam (LB), and a sensor 6 that detects incident light and outputs an output (sensor output (SO)) according to the incident light. The laser processing device 1 in FIG. 1 further includes a beam splitter 4, an acousto-optic modulator (AOM) 7 that modulates the laser beam (LB) emitted from the light source 2 by an acousto-optic effect, a galvanometer mirror unit 8, a table 10, and two filters (61, 62). In the laser processing device 1 of FIG. 1, a processing target is the wiring substrate (S), and the objective lens 3 focuses the laser beam (LB) onto a surface of the wiring substrate (S).

The light source 2 is composed of any laser oscillator capable of emitting a laser beam (LB). The light source 2 may emit a pulsed laser beam (LB). As an example, the light source 2 emits a UV laser beam with a wavelength of 355 nm, which is a third harmonic of a UV YAG laser. Since a UV laser beam has excellent linearity and is suitable for forming a minute opening (S31), it may be preferable as the laser beam (LB) used in the laser processing device 1 of the embodiment. However, the laser beam (LB) is not limited to a UV laser beam and may be a laser beam of any wavelength capable of drilling a hole in the wiring substrate (S).

The AOM 7 performs deflection and/or intensity modulation on the laser beam (LB) emitted from the light source 2 according to characteristics such as a frequency and/or an amplitude of a high-frequency control signal transmitted from the control device 5. The AOM 7 may start or stop the irradiation of the laser beam (LB) onto the wiring substrate (S) by starting or stopping the deflection or modulation operation according to a control signal transmitted from the control device 5.

The galvanometer mirror unit 8 includes a pair of reflecting mirrors 81 and driving units that rotate the reflecting mirrors 81. The driving units respectively rotate the two reflecting mirrors 81 around respective rotation axes orthogonal to each other in response to control signals transmitted from the control device 5. The pair of reflecting mirrors 81, rotated to a desired orientation, deflects the laser beam (LB) in a desired direction. An irradiation position of the laser beam (LB) on the wiring substrate (S) can be finely adjusted.

The objective lens 3 causes the laser beam (LB) incident on the objective lens 3 from the galvanometer mirror unit 8 to be incident perpendicularly onto the surface of the wiring substrate (S), which is the processing target, and focuses the laser beam (LB) at that incident position. That is, the objective lens 3 functions as a so-called fθ lens. Any optical lens capable of focusing the laser beam (LB) at the incident position of the laser beam (LB) on the surface of the wiring substrate (S) can be used as the objective lens 3.

The table 10 supports the wiring substrate (S) placed on the table 10 for the formation of the opening (S31). The table 10 moves, for example, reciprocally in two mutually orthogonal directions, thereby moving the wiring substrate (S) relative to the irradiated laser beam (LB). The table 10 may be, for example, an XY table, but may be any movable table capable of positioning any position on the wiring substrate (S) to the irradiation position of the laser beam (LB). The movement of the table 10 is preferably controlled by the control device 5.

The wiring substrate (S) illustrated in FIG. 2 includes a core substrate (S4), and conductor layers (S1) and insulating layers (S2) that are alternately laminated on both sides of the core substrate (S4). Each conductor layer (S1) is covered by an insulating layer (S2) laminated on the side opposite to the core substrate (S4) with respect to the conductor layer (S1). The conductor layers (S1) are formed of, for example, copper, but may be formed of any metal other than copper. The insulating layers (S2) are formed mainly of, for example, an epoxy resin, but may also be formed mainly of, for example, a thermosetting resin other than an epoxy resin, such as a bismaleimide triazine resin (BT resin), or a thermoplastic resin such as a fluororesin. Each insulating layer (S2) has via conductors (S3) formed therein that connect the conductor layers sandwiching the insulating layer (S2). The via conductors (S3) are formed in openings (S31) that penetrate the insulating layer (S2). By the laser processing device 1 of the embodiment and the laser processing method of the embodiment, openings such as the openings (S31) illustrated in FIGS. 1 and 2, which penetrate the insulating layers of the wiring substrate and expose portions of the conductor layers covered by the insulating layers, are formed in the insulating layers.

When the surface of the wiring substrate (S) is irradiated with the laser beam (LB), as illustrated in FIG. 3, a plasma state is generated at the irradiation spot due to temperature rise and ionization, and plasma light (PL) is emitted. For example, as illustrated in FIG. 3, when the laser beam (LB) irradiates a conductor layer (S1), plasma light (PL) primarily containing a wavelength specific to the material (for example, copper) constituting the conductor layer (S1) is emitted.

In the laser processing device 1 of the embodiment, the beam splitter 4 is positioned in an optical path (LP) of the laser beam (LB) between the light source 2 and the objective lens 3. The beam splitter 4 transmits the laser beam (LB) incident on the first light input/output surface 41 from the light source 2 side to the objective lens 3 side, that is., the wiring substrate (S) side. Further, the beam splitter 4 reflects the plasma light (PL) incident on a second light input/output surface 42, which is on the opposite side with respect to the first light input/output surface 41, so that the plasma light (PL) deviates from the optical path (LP) of the laser beam (LB). That is, the beam splitter 4 reflects the plasma light (PL) emitted from the wiring substrate (S) due to the irradiation of the laser beam (LB) and incident from the wiring substrate (S) side in a direction different from both a propagation direction of the laser beam (LB) and the opposite direction thereof.

The beam splitter 4 in FIG. 1 reflects the incident plasma light (PL) to a second direction (D2) different from a first direction (D1) along the optical path (LP) of the laser beam (LB). Further, the beam splitter 4 may reflect only light of at least a specific wavelength among the incident plasma light (PL) to the second direction (D2). As an example, the beam splitter 4 may reflect light of a specific wavelength among the plasma light (PL) incident on the second light input/output surface 42 in the second direction (D2), which forms an angle of substantially 90 degrees with the first direction (D1). The beam splitter 4 may be a dichroic beam splitter that transmits or reflects light of a specific wavelength incident on each light input/output surface.

A wavelength band of light that the beam splitter 4 transmits from the first light input/output surface 41 side to the second light input/output surface 42 side may include, for example, 355 nm, which is the wavelength of UV laser. Further, the specific wavelength of light that is among the plasma light (PL) incident on the second light input/output surface 42 and is reflected by the beam splitter 4 to the second direction (D2) may be the wavelength of plasma light emitted by a conductor layer (S1) of the wiring substrate (S) due to irradiation by the laser beam (LB). For example, the specific wavelength may be a wavelength in a range of 230 to 326 nm of plasma light emitted when the laser beam (LB) irradiates copper.

The beam splitter 4 may transmit light of a wavelength different from the wavelength of the light reflected in the second direction (D2) among the plasma light (PL) incident on the second light input/output surface 42 to the first light input/output surface 41 side. A wavelength band of light that the beam splitter 4 transmits to the first light input/output surface 41 side among the plasma light (PL) incident on the second light input/output surface 42 may include the wavelength of plasma light emitted by a constituent material of the wiring substrate (S) other than a conductor layer (S1) due to irradiation by the laser beam (LB). For example, even when a resin such as an epoxy resin constituting the insulating layers (S2), glass used as a reinforcing material, or materials such as silicon oxide or alumina constituting particles added to the insulating layers (S2) emit plasma light, incidence of the plasma light to the sensor 6 can be prevented. A wavelength band of light that the beam splitter 4 transmits from the second light input/output surface 42 to the first light input/output surface 41 side may be, for example, a wavelength band of 336 to 1200 nm.

The beam splitter 4 may reflect light of all wavelengths among the plasma light (PL) incident on the second light input/output surface 42 to the second direction (D2).

Even when the plasma light (PL) is reflected in this manner, as will be described later, by providing the filter 61 and/or filter 62, only light of a desired wavelength among the plasma light (PL) can be incident on the sensor 6.

In the laser processing device 1 of FIG. 1, a sensor unit 60 is constituted by the sensor 6, the filter 61, and the filter 62. The sensor unit 60 is positioned in the second direction (D2) such that the plasma light (PL) reflected by the beam splitter 4 toward the second direction (D2) enters the sensor unit 60. The filter 61 and the filter 62 are provided between the beam splitter 4 and the sensor 6. Light of a specific wavelength band among the light reflected by the beam splitter 4 toward the second direction (D2) passes through the filter 61 and the filter 62 and enters the sensor 6.

The sensor 6 outputs a sensor output (SO) to the control device 5 based on the plasma light (PL) reflected by the beam splitter 4 in the second direction (D2).

Specifically, the sensor 6 detects light that reaches the sensor 6 among the plasma light (PL) reflected by the beam splitter 4. The sensor 6 outputs a sensor output (SO), which is an electrical signal having, for example, a level or frequency corresponding to an intensity of the detected light. As an example, the sensor 6 may be a photomultiplier tube capable of detecting light with high sensitivity and high speed. However, the sensor 6 may be any photoelectric conversion element, such as a photodiode or phototransistor, capable of outputting an electrical signal with characteristics corresponding to the intensity of the incident light. The “intensity” of light such as the plasma light (PL) can be, for example, the energy of light flowing through a unit area per unit time (Poynting vector or power density).

The control device 5 is, for example, constituted by an integrated circuit device (IC), such as a microcomputer, a programmable logic device, or a field-programmable gate array, that executes a predetermined operation according to a command of an embedded program. The control device 5 may also be constituted by any of these ICs and its peripheral components. An IC, such as a microcomputer, and its peripheral components, which constitute the control device 5, function as an arithmetic part 51, a determination part 53, an irradiation start/stop control part 54, an irradiation condition control part 55, and an irradiation position control part 56, which are included in the control device 5, according to an algorithm of a sequentially executed program (execution program). In the example of FIG. 1, the control device 5 further includes a storage part 52 that stores a predetermined threshold for the sensor output (SO) output by the sensor 6.

The arithmetic part 51 performs a predetermined calculation commanded by the execution program, for example, a calculation on the sensor output (SO), and outputs a calculation result to the determination part 53. As one function, the arithmetic part 51 may calculate an integrated value for sensor outputs (SO) that respectively correspond to multiple irradiations of a pulsed laser beam (LB) to one processing position on the wiring substrate (S), which is the processing target, from the start of processing at that one processing position. This integrated value is hereinafter also simply referred to as the “sensor output integrated value”. The sensor output integrated value may be a simple sum of the sensor outputs (SO) from the start of processing at one processing position. Further, the sensor output integrated value may be a sum obtained by adding up, for all sensor outputs from the start of processing at the one processing position, the product of the sensor output (SO) for each irradiation among multiple irradiations at the one processing position and a unit time corresponding to the irradiation cycle.

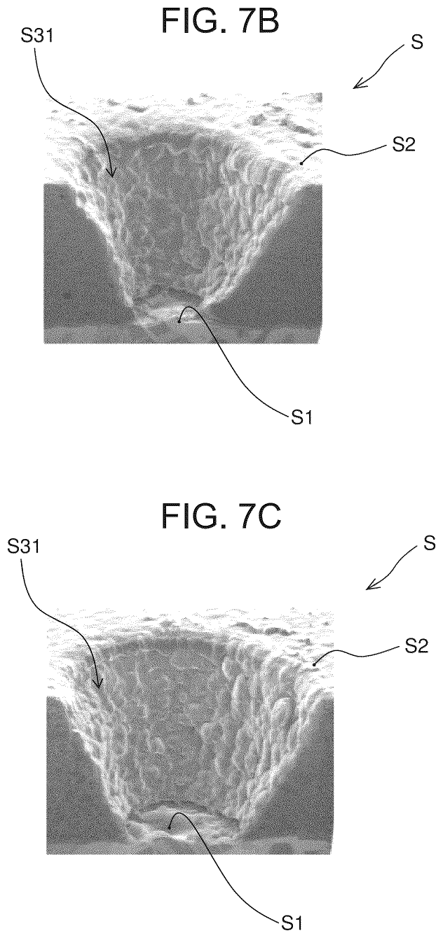

Further, it is thought that the sensor output integrated value may be a definite integral value of a time-dependent function of the sensor output (SO) obtained from each irradiation among multiple repetitive pulsed laser beam (LB) irradiations. That is, the relationship between the sensor output (SO) obtained from each irradiation among the repetitive pulsed laser beam (LB) irradiations (see FIGS. 6A to 6D) and the elapsed time from the start of irradiation is approximated by a function of an appropriate degree. Further, for that function, a definite integral value is calculated with respect to the elapsed time up to each irradiation among the repetitive pulsed laser beam (LB) irradiations. Then, each definite integral value may be used as the sensor output integrated value up to each irradiation among the repetitive irradiations for the formation of the opening (S31) by the laser beam (LB).

As one function, the determination part 53 compares a calculation result of the arithmetic part 51 with a predetermined threshold stored in the storage part 52 to determine whether or not there is a change in an irradiation site of the laser beam (LB). Then, the determination part 53 provides the determination result to the irradiation start/stop control part 54, the irradiation condition control part 55, and/or the irradiation position control part 56. The irradiation start/stop control part 54 transmits a signal to control the start and stop of the emission of the laser beam (LB) by the light source 2 and/or the switching between on and off of the AOM 7 based on the determination result of the determination part 53. The irradiation condition control part 55 outputs a signal to control the energy density or power of the laser beam (LB) emitted by the light source 2 based on the determination result of the determination part 53. When the laser beam (LB) is emitted in a pulsed form, the irradiation condition control part 55 may output a signal to control the irradiation cycle or pulse width based on the determination result of the determination part 53. Further, the irradiation condition control part 55 may output a signal to control the degree of intensity modulation of the laser beam (LB) by the AOM 7 based on the determination result of the determination part 53. The irradiation position control part 56 outputs a signal to control the deflection of the laser beam (LB) by the AOM 7 and/or the galvanometer mirror unit 8, as well as the start, stop, and movement direction of the table 10, based on the determination result of the determination part 53.

The storage part 52 may be included in a microcomputer or the like primarily constituting the control device 5, or may be a memory device provided separately from an IC such as a microcomputer. The storage part 52 may store a “predetermined first threshold” for the sensor output (SO) to be described later. Further, the storage part 52 may store a “predetermined second threshold” and a “predetermined third threshold” for the sensor output integrated value to be described later.

In the formation of an opening (S31) in an insulating layer (S2) of the wiring substrate (S) by the laser processing device 1 of the embodiment, for example, a laser beam (LB) in the UV band and in a pulsed form, is emitted from the light source 2. The laser beam (LB) is modulated and/or deflected by the AOM 7, further deflected in a predetermined direction by the galvanometer mirror unit 8, and enters the objective lens 3. Then the laser beam (LB), focused by the objective lens 3, irradiates the surface of the wiring substrate (S) at a desired processing position. When the laser beam (LB) irradiates a conductor layer (S1), plasma light (PL) containing light of a wavelength specific to the constituent material of the conductor layer (S1) is emitted from the wiring substrate (S).

The plasma light (PL) passes through the objective lens 3 in a direction opposite to a propagation direction of the laser beam (LB), is further deflected by the galvanometer mirror unit 8, and enters the beam splitter 4 from the second light input/output surface 42. Among the plasma light (PL), at least the plasma light (PL) having the wavelength specific to the constituent material of the conductor layer (S1) is reflected by the beam splitter 4 in the second direction (D2). Among the plasma light (PL), the plasma light (PL) having the wavelength specific to the constituent material of the conductor layer (S1) enters the sensor 6. The sensor 6 outputs a sensor output (SO) having a level corresponding to, for example, the intensity of the incident light to the control device 5.

The control device 5 controls the stopping of the irradiation of the wiring substrate (S) by the laser beam (LB), the irradiation conditions of the laser beam (LB), and the irradiation position of the laser beam (LB), based on the sensor output (SO). In other words, the control device 5 performs control such as stopping the irradiation of the laser beam (LB), adjusting the irradiation conditions of the laser beam (LB) such as the energy density, pulse width, and irradiation cycle, or shifting the irradiation position of the laser beam (LB) from one irradiation position to the next irradiation position, based on the sensor output (SO).

In the laser processing device 1 of the embodiment, the control device 5 is structured to recognize a change in the irradiation site (the site irradiated by the laser beam (LB)) on the wiring substrate (S), which is the processing target, based on the sensor output (SO). Further, the control device 5 is structured to, upon recognizing a change in the irradiation site of the laser beam (LB), reduce the processing capability of the laser beam (LB) and continue the irradiation of the wiring substrate (S) with the laser beam (LB). For example, a program embedded in a microcomputer or the like constituting the control device 5 may include a command that, when the control device 5 recognizes a change in the irradiation site of the laser beam (LB) based on the sensor output (SO), causes the control device 5 to reduce the processing capability of the laser beam (LB) and continue the irradiation.

In the following description, the description that “the control device 5 is structured to (perform a specific process)” includes the meaning that the execution program embedded in the microcomputer or the like constituting the control device 5 includes a command that causes the control device 5 to perform that specific process.

As an example for reducing the processing capability of the laser beam (LB), the control device 5 is structured to reduce the processing capability of the laser beam (LB) by lowering the energy density of the laser beam (LB). It is thought that the processing capability of the laser beam (LB) can be easily reduced by reducing the energy density.

However, the processing capability of the laser beam (LB) may be reduced by any processes capable of reducing the speed of enlarging or deepening the opening (S31), without being limited to reducing the energy density. For example, the processing capability of the laser beam (LB) may be reduced by narrowing the pulse width of the laser beam (LB).

In the laser processing device of the embodiment, instead of immediately stopping irradiation upon detecting a change in the plasma light spectrum or reaching a predetermined number of laser irradiations as in Patent Document 1, when a change in the irradiation site of the laser beam (LB) is recognized, the processing capability of the laser beam (LB) is reduced and the irradiation is continued. Therefore, compared to a drilling method such as that in Japanese Patent Application Laid-Open Publication No. 2013-43198, it may be possible to form an opening (S31) closer to a desired state, for example, in terms of opening diameter, while suppressing damage to the conductor layer (S1).

### Change in Irradiated Site

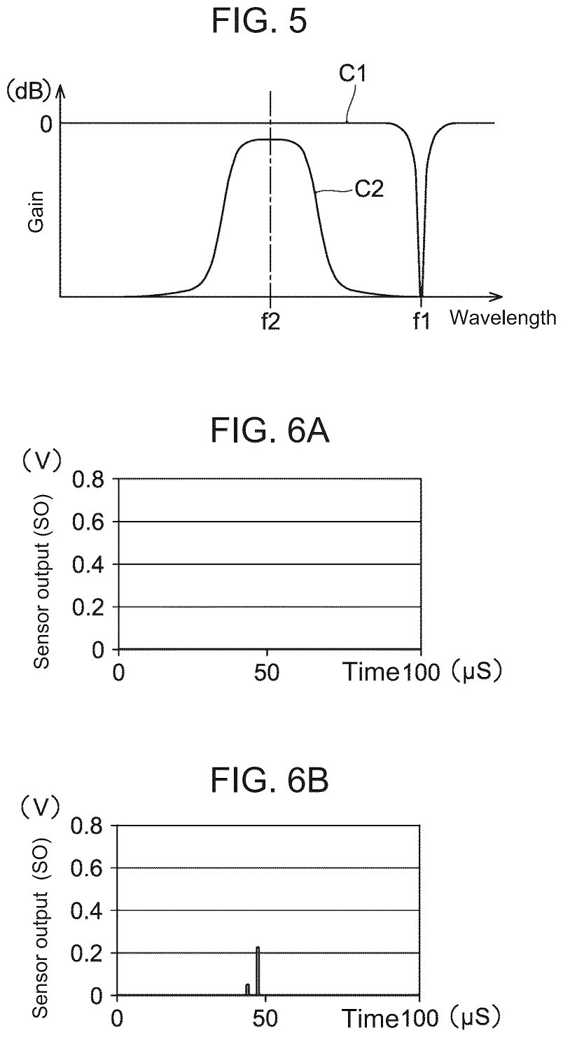

FIGS. 4A and 4B illustrate progress states of processing prior to the state illustrated in FIG. 3 in the laser processing device and laser processing method of the embodiment.

The processing state of the irradiation site in the laser processing device and laser processing method of the embodiment changes in the order of the states illustrated in FIGS. 4A, 4B, and 3.

In the wiring substrate (S), which is the processing target, as the irradiation site of the laser beam (LB) changes from the insulating layer (S2) to an interface between the insulating layer (S2) and the conductor layer (S1), and then to the conductor layer (S1), the plasma light (PL) is emitted from the wiring substrate (S) when the conductor layer (S1) is irradiated with the laser beam (LB). For example, as illustrated in FIG. 4A, while the laser beam (LB) is irradiating the insulating layer (S2), substantially no plasma light is emitted. Even when plasma light is emitted, its intensity is minimal, and the faintly emitted plasma light contains substantially no wavelength specific to the material (for example, copper) constituting the conductor layer (S1).

Next, as illustrated in FIG. 4B, when the laser beam (LB) begins to irradiate the conductor layer (S1) at the interface between the insulating layer (S2) and the conductor layer (S1), the plasma light (PL) containing a wavelength specific to the constituent material of the conductor layer (S1) starts to be emitted.

Then, when the laser beam (LB) irradiates the conductor layer (S1) (see FIG. 3), plasma light (PL) primarily containing a wavelength specific to the material (for example, copper) constituting the conductor layer (S1) is emitted with a higher intensity than the plasma light (PL) emitted in the processing state illustrated in FIG. 4B.

That is, as the irradiation site transitions from the insulating layer (S2) to the conductor layer (S1), the intensity of the plasma light (PL) increases. Further, in the plasma light (PL), the component of a wavelength specific to the constituent material of the conductor layer (S1) increases. Therefore, the intensity of the plasma light (PL) entering the sensor 6 via the beam splitter 4 and the filters (61, 62) increases. Then, the level or frequency of the sensor output (SO) changes according to the photoelectric conversion characteristics of the sensor 6. Therefore, the control device 5 can recognize a change in the irradiation site of the laser beam (LB).

Therefore, in one aspect, the control device 5 may be structured to recognize a change in the irradiation site of the laser beam (LB) based on the change in the level of the sensor output (SO) corresponding to the change in the intensity of the plasma light (PL). For example, the control device 5 may, in the determination part 53, compare the sensor output (SO) with a predetermined first threshold and recognize a change in the irradiation site of the laser beam (LB) based on the comparison result that the sensor output (SO) is equal to or exceeds the predetermined first threshold. As an example, the first threshold may be a value that is 10% or more and 20% or of a maximum value of the sensor output (SO) obtained when the laser beam (LB) irradiates the conductor layer (S1).

Further, it is thought that the above “sensor output integrated value” calculated for multiple pulsed laser beam (LB) irradiations at the same location on the wiring substrate (S), which is the processing target, has a correlation with formation progress of the opening (S31) after each of the multiple pulsed laser beam (LB) irradiations. Therefore, the control device 5 may be structured to recognize a change in the irradiation site of the laser beam (LB) when the sensor output integrated value satisfies a predetermined condition. For example, the “predetermined condition” may be that a rate of increase in the sensor output integrated value due to one laser beam (LB) irradiation is equal to or greater than a predetermined second threshold. In this case, the “predetermined second threshold” may be, for example, a rate of increase of 40% or more and 60% or less. Further, the “predetermined condition” may be that the sensor output integrated value reaches a predetermined second threshold. In this case, the “predetermined second threshold” is set, for example, based on a result of confirming in advance the correlation between the sensor output integrated value and the formation progress of the opening (S31).

Further, since the sensor output integrated value is thought to have a correlation with the formation progress of the opening (S31), the control device 5 may be further structured to terminate processing at each processing position (one processing position) currently being processed when the sensor output integrated value reaches a predetermined third threshold. The “predetermined third threshold” is set, for example, based on a result of confirming in advance the correlation between the sensor output integrated value and the formation progress of the opening (S31). By terminating processing at each processing position when the sensor output integrated value reaches the predetermined third threshold, it may be possible to form an opening close to a desired state.

### Filter Characteristics

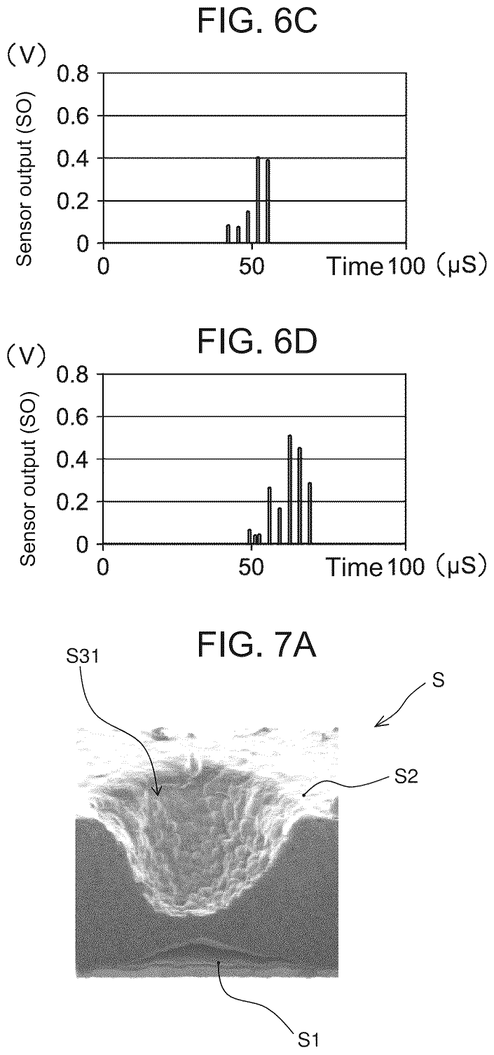

FIG. 5 illustrates an example of wavelength characteristics of gains (or attenuation rates) of the filter 61 and filter 62. The characteristics of the filter 61 are represented by a curve (C1), and the characteristics of the filter 62 are represented by a curve (C2). As illustrated in FIG. 5, the filter 61 may be a band-stop filter that significantly attenuates or blocks light in a specific wavelength band including a wavelength (f1). The filter 61 may also be a notch filter that significantly attenuates light in an extremely narrow wavelength band. The filter 61 may have a stop band that includes the wavelength of the laser beam (LB) emitted from the light source 2. When the filter 61 has such a stop band, even when a laser beam emitted from the light source unintentionally passes through or is reflected toward the sensor 6 (see FIG. 1), the laser beam is prevented from reaching the sensor 6 and being erroneously detected by the sensor 6. For example, when the light source emits a UV laser beam having a wavelength of 355 nm, the wavelength (f1) included in the stop band illustrated in FIG. 5 may be 355 nm.

On the other hand, as illustrated in FIG. 5, the filter 62 may be a bandpass filter that transmits only light in a specific wavelength band including a wavelength (f2) while attenuating or blocking light in other wavelength bands. The filter 62 preferably transmits only light in a wavelength band of plasma light emitted by a conductor layer of the wiring substrate. which is the processing target, due to irradiation by a laser beam from the light source. For example, the wavelength band of light transmitted by the filter 62 may be a wavelength band of plasma light emitted when a laser beam from the light source irradiates copper. Therefore, the wavelength (f2) included in the passband illustrated by the curve (C2) in FIG. 5 may be 326 nm.

### Sensor Output Measurement Example and Opening Observation Example

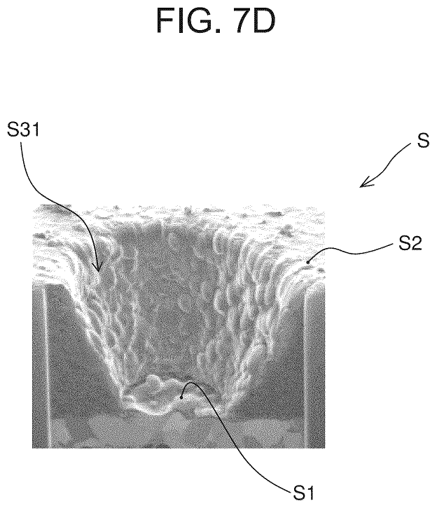

FIGS. 6A to 6D show measurement examples of sensor outputs (SO) obtained by forming an opening in an insulating layer of a wiring substrate using the laser processing device 1 of the embodiment illustrated in FIG. 1. In FIGS. 6A to 6D, the vertical axis represents the level (voltage) of the sensor output (SO) measured for each irradiation when a pulsed laser beam was repeatedly irradiated on the same location of the wiring substrate in a plan view. In FIGS. 6A to 6D, the horizontal axis is the time axis, showing progression of time with the repeated irradiation of the laser beam. The height of each vertical bar shown at each point on the horizontal axis indicates the level of the sensor output (SO) measured for one pulsed laser beam irradiation at that point in time. Further, each opening already formed at the time the measurement results shown in FIGS. 6A to 6D were obtained was cut along its axial direction and observed from an oblique angle above the opening. The images obtained from these observations are shown in FIGS. 7A to 7D. The observation images in FIGS. 7A to 7D respectively correspond to the openings formed by the laser beam irradiations for which the sensor output measurement results are shown in FIGS. 6A to 6D. As is evident from the cross-sectional images of the openings after each number of laser beam irradiations shown in FIGS. 7A to 7D, the investigations whose results are shown in FIG. 6A to FIG. 6D were respectively conducted for separate opening formations.

FIG. 6A shows the sensor outputs (SO) measured for five repeated laser beam irradiations. FIGS. 6B, 6C, and 6D respectively show the sensor outputs (SO) measured for eight, eleven, and fourteen repeated laser beam irradiations. Therefore, FIGS. 7A, 7B, 7C, and 7D are observation images of the openings formed by five, eight, eleven, and fourteen repeated laser beam irradiations, respectively. The investigations whose results are shown in FIGS. 6A to 6D and FIGS. 7A to 7D were conducted by irradiating an 8.5 μm thick insulating layer covering a 2.5 μm thick conductor layer with a pulsed laser beam having a wavelength of 355 nm and an energy density of 0.82 J/cm². The pulse width of the laser beam was 10 nsec, and the pulse frequency was 200 kHz. The investigations whose results are shown in FIGS. 6A to 7D were performed by disabling the function of the control device 5 (see FIG. 1), which reduces the processing capability of the laser beam upon recognizing a change in the irradiation site of the laser beam.

As shown in FIG. 6A, for up to five repeated laser beam irradiations, the level of the sensor output (SO) for each irradiation is approximately 0 V. In other words, as shown in FIG. 7A, the opening (S31) formed in the insulating layer (S2) by five repeated laser beam irradiations does not penetrate the insulating layer (S2), so no plasma light is emitted from the wiring substrate (S), or even when plasma light is faintly emitted, that plasma light contains substantially no wavelength component specific to copper or other materials constituting the conductor layer (S1). Therefore, since substantially no light reaches the sensor 6 illustrated in FIG. 1, only a sensor output (SO) of approximately 0 V is measured.

In the measurement results shown in FIG. 6B, a substantial level of sensor output (SO) is measured for the last two laser beam irradiations. For the last laser beam irradiation, a sensor output (SO) level of approximately 0.2 V is measured. Referring to FIG. 7B, an opening (S31) reaching the conductor layer (S1) is formed by eight repeated laser beam irradiations, with the surface of the conductor layer (S1) slightly exposed in the opening (S31). Therefore, plasma light is emitted from the wiring substrate (S). This plasma light contains a wavelength component specific to copper or the like constituting the conductor layer (S1), and since light of these wavelength components reaches the sensor 6 in FIG. 1, a sensor output (SO) greater than 0 V is measured. In the laser beam irradiations for which the sensor outputs (SO) are shown in FIG. 6B, as shown in FIG. 4B previously referred to, the irradiation site of the laser beam (LB) is thought to be near the interface between the insulating layer (S2) and the conductor layer (S1).

In the measurement results shown in FIG. 6C, the level of the sensor output (SO) rises to approximately 0.4 V for the last two irradiations. Referring to FIG. 7C, the bottom surface of the opening (S31) that has reached the conductor layer (S1) shows a larger exposure of the conductor layer (S1) compared to the conductor layer (S1) in FIG. 7B. Therefore, the intensity of the plasma light emitted from the wiring substrate (S) is higher than that during the irradiations for which the sensor outputs are shown in FIG. 6B, and since the emitted plasma light contains a wavelength component specific to copper or the like constituting the conductor layer (S1), the results shown in FIG. 6C show a higher level of sensor output (SO) than that in FIG. 6B.

Then, in the measurement results shown in FIG. 6D, sensor outputs (SO) with even higher levels than those of the measurement results shown in FIG. 6C are measured. Referring to FIG. 7D, although somewhat difficult to understand, as described later, an opening (S31) with a larger opening diameter than the opening (S31) in FIG. 7C is formed. Then, the conductor layer (S1) is exposed at the bottom surface of this opening (S31) with a larger opening diameter. Therefore, the results shown in FIG. 6D show sensor outputs with even higher levels than those in FIG. 6C. For the final irradiations among the laser beam irradiations for which the sensor outputs (SO) are shown in FIGS. 6C and 6D, similar to the processing state illustrated in FIG. 3 referred to above, the irradiation site of the laser beam is thought to be primarily the conductor layer.

In observing the openings (S31) whose images are shown in FIGS. 7A to 7D, the opening diameter at the bottom surface of each opening (S31) was measured using a measurement function of an observation device. The opening diameters at the bottom surfaces of the openings (S31) shown in FIGS. 7A, 7B, 7C, and 7D were 0 μm, approximately 4.2 μm, approximately 6.4 μm, and approximately 7.0 μm, respectively.

From the investigations whose results are shown in FIGS. 6A to 6D and FIGS. 7A to 7D, it is evident that by continuing laser beam irradiation even after the irradiation site on the wiring substrate, which is the processing target, changes from the insulating layer to the conductor layer, it is possible to form an opening with a larger opening diameter at its bottom surface. As a result, it may be possible to form an opening closer to a desired state.

### Laser Processing Method

The laser processing method of the embodiment primarily includes, as processes to be executed, several operations, controls, and electrical or optical processes performed by the structural components such as the control device of the laser processing device of the embodiment. The laser processing method of the embodiment may be performed using the laser processing device of the embodiment or may be performed without using the laser processing device of the embodiment. In the following, the laser processing method of the embodiment will be described, taking as an example the case where the laser processing device 1 of the embodiment is used, with reference again to FIG. 1 and the like and using the reference numeral symbols assigned in FIG. 1. Unless specifically mentioned otherwise in the following description, the operations, controls, and various processes and the like performed by the structural elements described with respect to the laser processing device of the embodiment may be included in the laser processing method of the embodiment.

The laser processing method of the embodiment is a laser processing method for a wiring substrate such as the wiring substrate (S) illustrated in FIG. 1. The laser processing method of the embodiment includes forming an opening (S31) in an insulating layer (S2) of the wiring substrate (S) to expose a portion of a conductor layer (S1) covered by the insulating layer (S2) by irradiating a surface of the wiring substrate (S) with a laser beam (LB). The laser processing method of the embodiment further includes causing the sensor 6 to output a sensor output (SO) based on plasma light (PL)emitted from the wiring substrate (S) due to the irradiation of the laser beam (LB) by allowing the plasma light (PL) to enter the sensor 6.

In other words, when the laser processing device 1 of FIG. 1 is used, in the implementation of the laser processing method of the embodiment, a laser beam (LB), for example, in the UV band and in a pulsed form, is emitted from the light source 2. The laser beam (LB) irradiates the surface of the wiring substrate (S) via the AOM 7, the beam splitter 4, the galvanometer mirror unit 8, and the objective lens 3. When the laser beam (LB) irradiates the conductor layer (S1), plasma light (PL) containing light of a wavelength specific to the constituent material of the conductor layer (S1) is emitted. The plasma light (PL) enters the beam splitter 4 via the objective lens 3 and the galvanometer mirror unit 8. Among the plasma light (PL), at least the plasma light (PL) having a wavelength specific to the constituent material of the conductor layer (S1) is reflected by the beam splitter 4 in the second direction (D2), passes through the filters (61, 62), and enters the sensor 6. The sensor 6 outputs a sensor output (SO) with a level corresponding to, for example, the intensity of the incident light.

By irradiating a predetermined location on the wiring substrate (S) with the laser beam (LB), an opening (S31) can be formed at the predetermined location. Then, in the laser processing method of the embodiment, forming the opening (S31) includes, upon recognizing a change in the irradiation site of the laser beam (LB) based on the sensor output (SO), reducing the processing capability of the laser beam (LB) and continuing the irradiation of the laser beam (LB).

In the laser processing method of the embodiment, reducing the processing capability of the laser beam (LB) may include reducing the energy density of the laser beam (LB). It is thought that the processing capability of the laser beam (LB) can be easily reduced by reducing the energy density. Further, in the laser processing method of the embodiment, reducing the processing capability of the laser beam (LB) may include narrowing the pulse width of the laser beam (LB) emitted in a pulsed form from the light source 2. In the laser processing method of the embodiment, the processing capability of the laser beam (LB) may be reduced using any method, not limited to reducing the energy density or the pulse width.

As described with respect to the laser processing device of the embodiment, the intensity of the plasma light (PL) changes in according to a change in the constituent material of the wiring substrate (S) irradiated by the laser beam (LB), and further, the sensor output (SO) also changes. Therefore, based on the sensor output (SO), for example, using the control device 5 of FIG. 1, a change in the irradiation site of the laser beam (LB) from the insulating layer (S2) to the conductor layer (S1) can be recognized. Therefore, in the laser processing method of the embodiment, the change in the irradiation site of the laser beam (LB) may be recognized based on a change in the level of the sensor output (SO) corresponding to a change in the intensity of the plasma light (PL). For example, the sensor output (SO) may be compared with a predetermined first threshold, and a change in the irradiation site of the laser beam (LB) may be recognized when the sensor output (SO) is equal to or exceeds the predetermined first threshold. As an example, the first threshold may be a value that is 10% or more and 20% or of a maximum value of the sensor output (SO) obtained when the laser beam (LB) irradiates the conductor layer (S1).

As described with respect to the laser processing device of the embodiment, the integrated value of the sensor output (SO) (sensor output integrated value), calculated for multiple irradiations of a pulsed laser beam (LB) at the same position on the wiring substrate (S), which is the processing target, is thought to have a correlation with the formation progress of the opening (S31). To utilize this correlation, the laser processing method of the embodiment may further include calculating the sensor output integrated value.

In other words, the laser processing method of the embodiment may include repeating the irradiation of a pulsed laser beam (LB) multiple times at one processing position on the wiring substrate (S). Further, the laser processing method of the embodiment may include calculating the sensor output integrated value, which is the integrated value from the start of processing at the one processing position for the sensor outputs (SO) corresponding the multiple irradiations of the laser beam (LB). Then, in the laser processing method of the embodiment, a change in the irradiation site of the laser beam (LB) may be recognized when the sensor output integrated value satisfies a predetermined condition. For example, the “predetermined condition” may be that a rate of increase in the sensor output integrated value due to one laser beam (LB) irradiation is equal to or greater than a predetermined second threshold. Further, the “predetermined condition” may be that the sensor output integrated value reaches a predetermined second threshold.

In the laser processing method of the embodiment, the sensor output integrated value may be a simple sum of the sensor outputs (SO) from the start of processing at the one processing position. Further, the sensor output integrated value may be a sum obtained by adding up, for all sensor outputs from the start of processing at the one processing position, the product of the sensor output (SO) for each irradiation among multiple irradiations at the one processing position and a unit time corresponding to the irradiation cycle. Further, as described with respect to the laser processing device of the embodiment, the sensor output integrated value may be a definite integral value of a time-dependent function of the sensor output (SO) obtained from each irradiation among multiple repetitive pulsed laser beam (LB) irradiations.

Further, since the sensor output integrated value is thought to have a correlation with the formation progress of the opening (S31), in the laser processing method of the embodiment, processing at a processing position currently being processed (one processing position) may be terminated when the sensor output integrated value reaches a predetermined third threshold. By terminating processing at each processing position when the sensor output integrated value reaches the predetermined third threshold, it may be possible to form an opening close to a desired state at each processing position.

As described above, in the laser processing device and laser processing method of the embodiment, the irradiation with the laser beam is continued even after a change in the irradiation site of the laser beam is recognized. Therefore, compared to a laser processing device or method in which irradiation is stopped upon detecting a change in the irradiation site of the laser beam, it is thought that an opening closer to a desired state can be formed.

Further, in the laser processing device and laser processing method of the embodiment, when a change in the irradiation site of the laser beam is recognized, the processing capability of the laser beam is reduced, and the irradiation is continued. Therefore, by continuing the processing of the insulating layer, it is thought that the opening can be formed closer to a desired state, while damage to the conductor layer due to continued irradiation can be suppressed by reducing the processing capability of the laser beam. Therefore, it is thought that issues such as penetration of the conductor layer, which could occur by continuing irradiation after the irradiation site of the laser beam changes from the insulating layer to the conductor layer, can be prevented.

With the progress in miniaturization of wiring patterns in wiring substrates, small-diameter via conductors are desired. Small-diameter via conductors require small-diameter openings, and for forming small-diameter openings, the use of a short-wavelength, short-pulse laser beam may be preferable. On the other hand, a short-wavelength, short-pulse laser beam has high processing capability for copper, so continuing irradiation with a laser beam that maintains its processing capability after the irradiation site of the laser beam changes to a conductor layer is likely to cause excessive damage to the conductor layer. In contrast, in the laser processing device and laser processing method of the embodiment, when a change in the irradiation site of the laser beam is detected, irradiation is continued with a laser beam whose processing capability has been reduced. Therefore, the laser processing device and laser processing method of the embodiment may be particularly suitable for forming small-diameter via conductors and, further, for manufacturing wiring substrates having fine wiring patterns.

The laser processing device of the embodiment is not limited to those having the structure exemplified in FIG. 1 or the structures exemplified in the present specification. For example, the functions of filters (61, 62) may be incorporated into the beam splitter 4 or the sensor 6. Further, the laser processing device of the embodiment may include any structural elements other than those illustrated in FIG. 1. Further, the laser processing method of the embodiment is not limited to the method described with reference to FIG. 1. The laser processing method of the embodiment may include any additional processes beyond those described above, and some of the processes described above may be omitted.

Japanese Patent Application Laid-Open Publication No. 2013-43198 describes a drilling method and a laser processing device for forming a laser-processed hole that reaches from a first member to a second member by irradiating, with a laser beam, a workpiece composed of the first member and the second member that are connected. In the method and processing device described in Japanese Patent Application Laid-Open Publication No. 2013-43198, a minimum value and a maximum value are set in advance for the number of shots of the pulsed laser beam. The irradiation of the pulsed laser beam is stopped based on a magnitude relationship between the minimum and maximum values and the number of shots of the pulsed laser beam already irradiated, and based on a change in the spectrum emitted by plasma generated by the irradiation of the pulsed laser beam.

In the drilling method and laser processing device described in Japanese Patent Application Laid-Open Publication No. 2013-43198., the irradiation of the pulsed laser beam is stopped when there is a change in the spectrum of the plasma or when the number of irradiations of the pulsed laser beam reaches a preset number of shots. Therefore, the laser-processed hole may not necessarily have a desired opening diameter.

A laser processing device according to an embodiment of the present invention is for forming an opening in an insulating layer of a wiring substrate to expose a portion of a conductor layer covered by the insulating layer, and includes: a light source that emits a laser beam; an objective lens that focuses the laser beam onto a surface of the wiring substrate; a control device that controls an irradiation condition of the laser beam; and a sensor that outputs to the control device a sensor output based on plasma light emitted from the wiring substrate due to irradiation of the laser beam. The control device is structured to, upon recognizing a change in an irradiation site of the laser beam based on the sensor output, reduce processing capability of the laser beam and continue the irradiation.

A laser processing method for a wiring substrate according to another embodiment of the present invention includes: forming an opening in an insulating layer of the wiring substrate to expose a portion of a conductor layer covered by the insulating layer by irradiating a surface of the wiring substrate with a laser beam, and causing a sensor to output a sensor output based on plasma light emitted from the wiring substrate due to the irradiation of the laser beam by allowing the plasma light to enter the sensor. The forming of the opening includes, upon recognizing a change in an irradiation site of the laser beam based on the sensor output, reducing processing capability of the laser beam and continuing the irradiation of the laser beam.

According to an embodiment of the present invention, it is thought that an opening closer to a desired state can be formed in an insulating layer of a wiring substrate while suppressing damage to an underlying conductor layer.

Obviously, numerous modifications and variations of the present invention are possible in light of the above teachings. It is therefore to be understood that within the scope of the appended claims, the invention may be practiced otherwise than as specifically described herein.

1. A laser processing device for forming an opening in an insulating layer of a wiring substrate, comprising:
a light source that emits a laser beam;
an objective lens configured to focus the laser beam onto a surface of a wiring substrate;
a control device comprising circuitry configured to control an irradiation condition of the laser beam; and
a sensor that outputs to the control device a sensor output based on plasma light emitted from the wiring substrate due to irradiation of the laser beam,
wherein the circuitry of the control device is configured to recognize a change in an irradiation site of the laser beam based on the sensor output, reduce processing capability of the laser beam and continue the irradiation upon.

2. The laser processing device according to claim 1, wherein the circuitry of the control device is configured to recognize the change in the irradiation site based on a change in a level of the sensor output corresponding to a change in an intensity of the plasma light.

3. The laser processing device according to claim 1, wherein the circuitry of the control device is configured to calculate an integrated value from a start of processing at one processing position for the sensor output corresponding to each of irradiations of the laser beam to the one processing position on the wiring substrate, and to recognize a change in the irradiation site when the integrated value satisfies a predetermined condition.

4. The laser processing device according to claim 1, wherein the circuitry of the control device is configured to lower the processing capability by reducing an energy density of the laser beam.

5. The laser processing device according to claim 1, further comprising:
a beam splitter positioned in an optical path between the light source and the objective lens; and
a filter positioned between the beam splitter and the sensor and having a stop band including a wavelength of the laser beam,
wherein the beam splitter transmits the laser beam and reflects the plasma light emitted from the wiring substrate such that the plasma light is deflected from the optical path of the laser beam.

6. The laser processing device according to claim 2, wherein the circuitry of the control device is configured to calculate an integrated value from a start of processing at one processing position for the sensor output corresponding to each of irradiations of the laser beam to the one processing position on the wiring substrate, and to recognize a change in the irradiation site when the integrated value satisfies a predetermined condition.

7. The laser processing device according to claim 2, wherein the circuitry of the control device is configured to lower the processing capability by reducing an energy density of the laser beam.

8. The laser processing device according to claim 2, further comprising:
a beam splitter positioned in an optical path between the light source and the objective lens; and
a filter positioned between the beam splitter and the sensor and having a stop band including a wavelength of the laser beam,
wherein the beam splitter transmits the laser beam and reflects the plasma light emitted from the wiring substrate such that the plasma light is deflected from the optical path of the laser beam.

9. The laser processing device according to claim 3, wherein the circuitry of the control device is configured to lower the processing capability by reducing an energy density of the laser beam.

10. The laser processing device according to claim 3, further comprising:
a beam splitter positioned in an optical path between the light source and the objective lens; and
a filter positioned between the beam splitter and the sensor and having a stop band including a wavelength of the laser beam,
wherein the beam splitter transmits the laser beam and reflects the plasma light emitted from the wiring substrate such that the plasma light is deflected from the optical path of the laser beam.

11. The laser processing device according to claim 4, further comprising:
a beam splitter positioned in an optical path between the light source and the objective lens; and
a filter positioned between the beam splitter and the sensor and having a stop band including a wavelength of the laser beam,
wherein the beam splitter transmits the laser beam and reflects the plasma light emitted from the wiring substrate such that the plasma light is deflected from the optical path of the laser beam.

12. The laser processing device according to claim 6, wherein the circuitry of the control device is configured to lower the processing capability by reducing an energy density of the laser beam.

13. The laser processing device according to claim 6, further comprising:
a beam splitter positioned in an optical path between the light source and the objective lens; and
a filter positioned between the beam splitter and the sensor and having a stop band including a wavelength of the laser beam,
wherein the beam splitter transmits the laser beam and reflects the plasma light emitted from the wiring substrate such that the plasma light is deflected from the optical path of the laser beam.

14. The laser processing device according to claim 12, further comprising:
a beam splitter positioned in an optical path between the light source and the objective lens; and
a filter positioned between the beam splitter and the sensor and having a stop band including a wavelength of the laser beam,
wherein the beam splitter transmits the laser beam and reflects the plasma light emitted from the wiring substrate such that the plasma light is deflected from the optical path of the laser beam.

15. A laser processing method for a wiring substrate, comprising:
irradiating an insulating layer of a wiring substrate with a laser beam such that an opening is formed in the insulating layer and exposes a portion of a conductor layer covered by the insulating layer; and
causing a sensor to output a sensor output based on plasma light emitted from the wiring substrate irradiated with the laser beam,
wherein the irradiating includes recognizing a change in an irradiation site of the laser beam based on the sensor output, and reducing processing capability of the laser beam based on the sensor output while continuing irradiation of the laser beam.

16. The laser processing method according to claim 15, wherein the reducing of the processing capability includes reducing an energy density of the laser beam.

17. The laser processing method according to claim 15, wherein the change in the irradiation site is recognized based on a change in a level of the sensor output corresponding to a change in an intensity of the plasma light.

18. The laser processing method according to claim 15, further comprising:
repeating irradiation of the laser beam a plurality of times at one processing position on the wiring substrate; and
calculating an integrated value from a start of processing at one processing position for the sensor output corresponding to the irradiation of each of the times,
wherein the change in the irradiation site is recognized when the integrated value satisfies a predetermined condition.

19. The laser processing method according to claim 16, wherein the change in the irradiation site is recognized based on a change in a level of the sensor output corresponding to a change in an intensity of the plasma light.

20. The laser processing method according to claim 16, further comprising:
repeating irradiation of the laser beam a plurality of times at one processing position on the wiring substrate; and
calculating an integrated value from start of processing at one processing position for the sensor output corresponding to the irradiation of each of the times,
wherein the change in the irradiation site is recognized when the integrated value satisfies a predetermined condition.
